(19) United States
(12) Patent Application Publication
(10) Pub. No.: US 2007/0102794 A1
(43) Pub. Date: May 10, 2007

(54) Lead arrangement and chip package using the same

(76) Inventors: Chao-Yang Hsiao, Hsin-Tien City (TW); Hsing-Chou Hsu, Hsin-Tien City (TW)

Correspondence Address: J.C. Patents, Inc., Suite 250, 4 Venture, Irvine, CA, 92618, US

(21) Appl. No.: 11/410,749

(22) Filed: Apr. 24, 2006

(30) Foreign Application Priority Data
Nov. 10, 2005 (JP) 94139390

(51) Int. Cl. H01L 23/495

(52) U.S. Cl. 257/666

(57) ABSTRACT

A lead arrangement applied to the leadframe of a chip package is provided. The lead arrangement includes at least a pair of differential signal leads and at least a non-differential signal lead. The pair of differential signal leads includes a first differential signal lead and a second differential signal lead. The non-differential signal lead is disposed between the first differential signal lead and the second differential signal lead.

### CROSS-REFERENCE TO RELATED APPLICATION

This application claims the priority benefit of Taiwan application serial no. 94139390, filed on Nov. 10, 2005. All disclosure of the Taiwan application is incorporated herein by reference.

### BACKGROUND OF THE INVENTION

1. Field of the Invention

The present invention relates to a lead arrangement. More particularly, the present invention relates to a lead arrangement for a chip package.

2. Description of the Related Art

In the semiconductor industry, the fabrication of integrated circuits (ICs) may be divided into three stages: IC design, IC processing and IC packaging. In the IC processing stage, a die is produced through the steps of wafer production, integrated circuits fabrication and wafer sawing or cutting. Each wafer has an active surface, which generally means the surface has active devices formed thereon. After forming integrated circuits on the wafer, a plurality of bonding pads is disposed on the active surface. Therefore, the die sawn out from the wafer can be electrically connected to a carrier through these bonding pads. The carrier is, for example, a leadframe or a package substrate. The die is connected to the carrier through wire-bonding or flip-chip bonding so that the bonding pads on the die can be electrically connected with various contacts of the carrier to form a chip package.

According to the wire-bonding technique, most low pin-count IC packages have a leadframe-based design. After the processes of wafer sawing, die bonding, wire bonding, molding, and trimming/forming, a conventional leadframe-based chip package is almost completed.

FIG. 1A is a schematic cross-sectional view showing a conventional chip package disposed on a circuit board. As shown in FIG. 1A, the conventional chip package 100 is suitable for disposing on a circuit board B. The chip package 100 includes a chip 110, a leadframe 120, a plurality of bonding wires 130 and a molding compound 140. The chip 110 has an active surface 112 and a plurality of bonding pads 114 disposed on the active surface 112. The leadframe 120 has a die pad 122 and a plurality of leads 124. The chip 110 is disposed on the die pad 122. In addition, each bonding pad 114 on the chip 110 is electrically connected to one of the leads 124 of the leadframe 120 through one of the bonding wires 130. The molding compound 140 encapsulates the chip 110, the bonding wires 130, the die pad 122 and a portion of each of the leads 124. The molding compound 140 protects the chip 110 and the bonding wires 130 against the penetration of moisture, heat and interfering noise. Furthermore, the molding compound 140 also provides support to these bonding wires 130 so that the package can be gripped by hands.

FIG. 1B is a diagram showing a conventional lead arrangement for the chip package shown in FIG. 1A. It should be noted that for subsequent explanation only a few of the leads 124 are shown in FIG. 1B. As shown in FIG. 1B, some of the leads 124 formed a lead arrangement (LA) including two pairs of differential signal leads 124(a), 124(b), 124(c), 124(d) and two non-differential signal leads 124(e), 124(f). The adjacent pair of differential signal leads 124(a) and 124(b) transmits a positive signal and a negative signal respectively. Furthermore, the direction of transmission is from the chip 110 to the circuit board B. Similarly, another adjacent pair of differential signal leads 124(c) and 124(d) transmits a positive signal and a negative signal respectively. However, the transmission direction is from the circuit board B to the chip 110.

In high-speed and high-frequency signal transmission, the equivalent capacitance between neighboring differential signal leads having the same transmission direction will be substantially increased. As a result, the impedance of the aforementioned differential signal leads will drop. Hence, the impedance mismatch between the bonding wires and the differential signal leads will get worse, which leads to a deterioration of the signal transmission quality of the differential signal leads.

### SUMMARY OF THE INVENTION

The present invention provides a lead arrangement that can be applied to the leadframe of a chip package. The lead arrangement includes at least a pair of differential signal leads and at least a non-differential signal lead. The pair of differential signal leads includes a first differential signal lead and a second differential signal lead. The non-differential signal lead is disposed between the first differential signal lead and the second differential signal lead.

The present invention also provides a chip package suitable for mounting on a circuit board. The chip package includes a chip, a leadframe, a plurality of bonding wires, and a molding compound. The chip has an active surface and a plurality of pads disposed thereon. The leadframe has a die pad and a plurality of leads. The chip is disposed on the die pad. Some of the leads form a lead arrangement. The lead arrangement includes at least a pair of differential signal leads and at least a non-differential signal lead. The pair of differential signal leads includes a first differential signal lead and a second differential signal lead, and the non-differential signal lead is disposed between the first differential signal lead and the second differential signal lead. In addition, each bonding pad on the chip is electrically connected to one of the leads in the leadframe through a corresponding bonding wire. The molding compound encapsulates the chip, the bonding wires, the die pad and a portion of the leads.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a schematic cross-sectional view showing a conventional chip package disposed on a circuit board.

FIG. 1B is a diagram showing a conventional lead arrangement for the chip package shown in FIG. 1A.

FIG. 2A is a schematic cross-sectional view showing a chip package disposed on a circuit board according to one embodiment of the present invention.

FIG. 2B is a diagram showing a lead arrangement for the chip package shown in FIG. 2A.

FIG. 3 is a diagram showing a lead arrangement for a chip package according to another embodiment of the present invention.

FIG. 4 is a diagram showing a lead arrangement for a chip package according to yet another embodiment of the present invention.

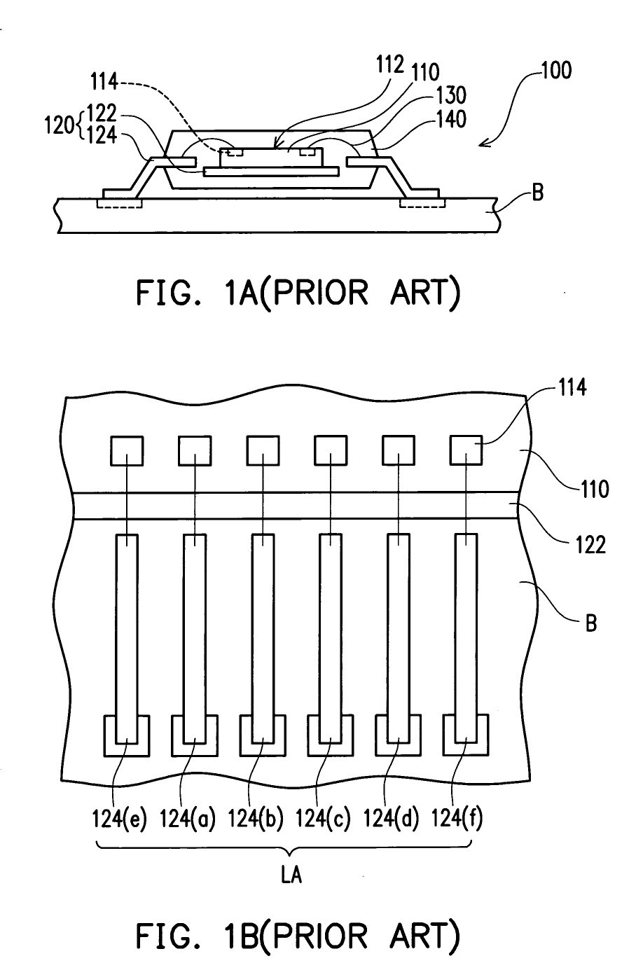

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

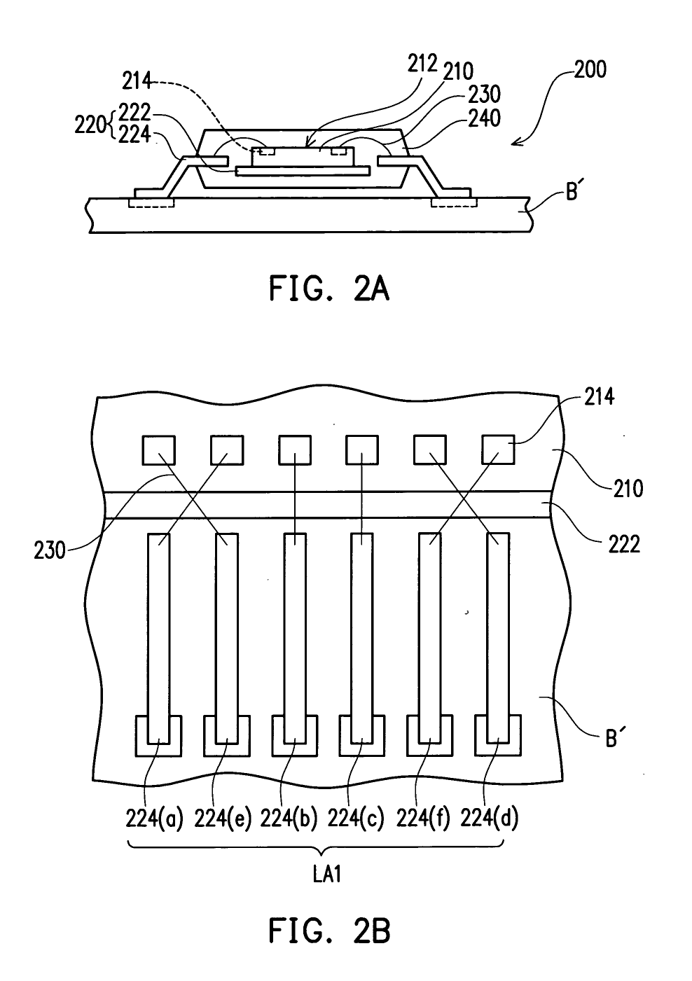

FIG. 2A is a schematic cross-sectional view showing a chip package disposed on a circuit board according to one embodiment of the present invention. The chip package 200 in the present embodiment is mounted on a circuit board B′. The chip package 200 includes a chip 210, a leadframe 220, a plurality of bonding wires 230 and a molding compound 240. The chip 210 has an active surface 212 and a plurality of bonding pads 214 disposed thereon. The leadframe 220 has a die pad 222 and a plurality of leads 224. The chip 210 is disposed on the die pad 222. Furthermore, each bonding pad 214 on the chip 210 is electrically connected to one of the leads 224 of the leadframe 220 through a corresponding bonding wire 230. The molding compound 240 encapsulates the chip 210, the bonding wires 230, the die pad 222 and a portion of the leads 224. The molding compound 240 protects the chip 210 and the bonding wires 230 against the penetration of moisture, heat and interfering noise. Furthermore, the molding compound 240 also provides support to these bonding wires 230 and a body for holding.

FIG. 2B is a diagram showing a lead arrangement for the chip package shown in FIG. 2A. It should be noted only a few of the leads 224 are shown in FIG. 2B for the following description. As shown in FIG. 2B, the leads 224 form a lead arrangement LA1 that can be applied to a leadframe 220 (see FIG. 2A) of a chip package 200. The leadframe arrangement LA1 includes at least a pair of differential signal leads 224(a) and 224(b) and at least a non-differential signal lead 224(e) disposed between the differential signal leads 224(a) and 224(b). In addition, FIG. 2B also shows another pair of differential signal leads 224(c) and 224(d) and another non-differential signal lead 224(f) disposed between the differential signal leads 224(c) and 224(d). The differential signal leads 224(a) and 224(b) transmit a positive signal and a negative signal (or transmit a negative signal and a positive signal) respectively. The directions of transmitting the differential signal leads 224(a) and 224(b) are identical, for example, from the chip 210 to the circuit board B′. On the other hand, the differential signal leads 224(c) and 224(d) transmit a positive signal and a negative signal (or transmit a negative signal and a positive signal) respectively. The directions of transmitting the differential signal leads 224(c) and 224(d) are identical, for example, from the circuit board B′ to the chip 210.

In the present embodiment, the non-differential signal lead 224(e) is a floating lead, a power lead or a ground lead, for example. Similarly, the non-differential signal lead 224(f) is a floating lead, a power lead or a ground lead, for example. In the present embodiment, the non-differential signal lead 224(e) is disposed between the differential signal leads 224(a) and 224(b) whose transmission directions are the same. Hence, the equivalent capacitance between the differential signal leads 224(a) and 224(b) will drop, resulting in an increase of the impedance of the differential signal leads 224(a) and 224(b). As a result, the impedance mismatch between the bonding wires 230 and the differential signal leads 224(a) and 224(b) will be reduced so that the quality of signal transmission is improved. For the same reason, with the non-differential signal lead 224(f) disposed between the differential signal leads 224(c) and 224(d) both having the same transmission direction, the transmission quality of the differential signal leads 224(c) and 224(d) is also improved.

It should be noted that only one non-differential signal lead 224(e) is disposed between the differential signal leads 224(a) and 224(b) in the present embodiment. However, the designer may choose the number of non-differential signal leads 224(e) disposed between the differential signal leads 224(a) and 224(b) according to the actual requirements. Similarly, the designer may choose the number of non-differential signal leads 224(f) disposed between the differential signal leads 224(c) and 224(d) according to the actual requirements. Hence, the aforementioned embodiment is used as an example only and should by no means limit the scope of the present invention.

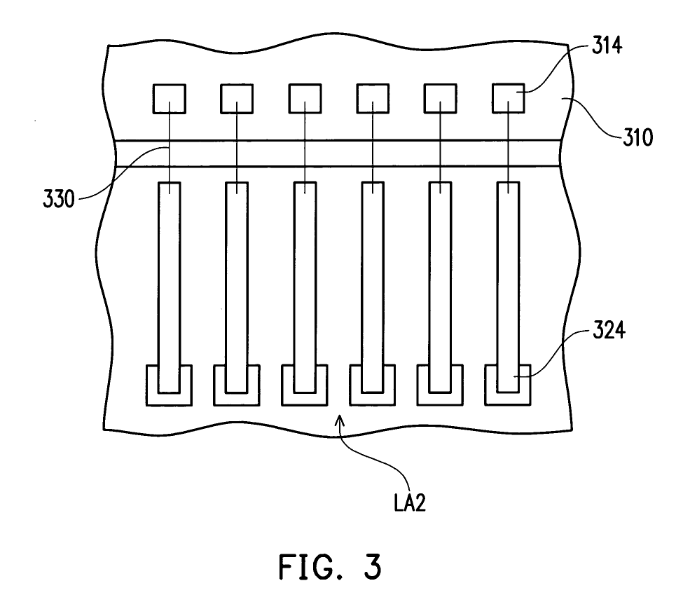

FIG. 3 is a diagram showing a lead arrangement for a chip package according to another embodiment of the present invention. As shown in FIG. 3, the lead arrangement LA2 of some of the leads 324 is identical to the lead arrangement LA1 of some of the leads 224 in FIG. 2B. One major difference of the leads arrangement LA2 in FIG. 3 from the lead arrangement LA1 in FIG. 2B is the electrical connection way of the bonding wires 330 of the leads 324 of the lead arrangement LA2 with the chip 310. In the embodiment shown in FIG. 2B, some of the bonding wires 230 will cross each other in space. However, in the embodiment shown in FIG. 3, the bonding wires 330 do not cross each other. In other words, some of the bonding pads 314 on the chip 310 are arranged to correspond with some of the leads 324 in the lead arrangement LA2.

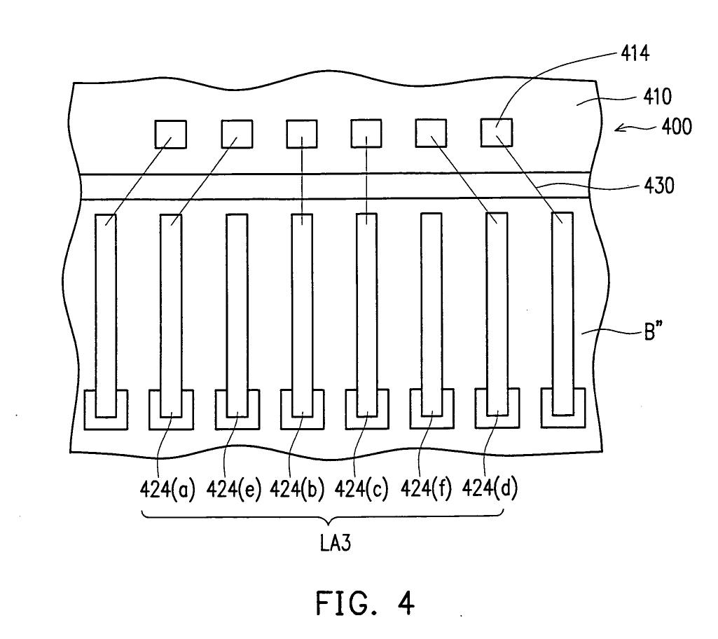

FIG. 4 is a diagram showing a lead arrangement for a chip package according to yet another embodiment of the present invention. As shown in FIG. 4, the lead arrangement LA3 of some of the leads 424 is identical to the lead arrangement LA2 of some of the leads 324 in FIG. 3. One major difference is that the non-differential signal lead 424(e) between the differential signal leads 424(a) and 424(b) and the non-differential signal lead 424(f) between the differential signal leads 424(c) and 424(d) are not electrically connected to the bonding pads 414. In other words, the non-differential signal leads 424(e) and 424(f) are floating leads.

Therefore, the chip package 400 having the lead arrangement LA3 shown in FIG. 4 can be mounted on a circuit board B″. Furthermore, the chip package 400 can be electrically connected with other active devices (not shown) or passive devices (not shown) to form an electronic device with a specific function. In addition, one end of the non-differential signal leads 424(e) and 424(f) serving as a floating lead in the chip package 400 can be electrically connected to the circuit board B″. Yet, the other end of the non-differential signal leads 424(e) and 424(f) is not electrically connected to any external power terminal, external ground terminal or other device. However, one end of the leads such as the power lead, the ground lead and the differential signal leads 424(a), 424(b), 424(c), 424(d) can be electrically connected to other device through the circuit board B″ and its internal circuits. Moreover, the other end of these leads can be electrically connected with the bonding pads 414 on the chip 410 through the bonding wires 430.

The chip package with the lead arrangement of the present inventions may be disposed on a circuit board and connected other active devices and passive devices to form an electronic apparatus with specific functions. In the electronic apparatus, the power leads, ground leads, and signal leads may connect other devices through the bonding pads and internal circuits in the circuit board. However, the abovementioned floating leads is only connected to the bonding pads in the circuit board, but not to any external power terminals, external ground terminals, or other devices.

In summary, the lead arrangement and the chip package using the lead arrangement in the present invention has at least the following advantages:

1. Because at least one non-differential signal lead is disposed between a pair of differential signal leads, the equivalent capacitance between the differential signal leads having the same transmission direction will drop in high-speed and high-frequency signal transmission. Hence, the impedance of the pair of differential signal leads will increase so that the impedance mismatch between the bonding wires and the differential signal leads is reduced.

2. With improvement in the impedance mismatch between the bonding wires and the differential signal leads, the return loss can be increased when high frequency signal is transmitted from the bonding wires to the differential signal lead.

3. With improvement in the impedance mismatch between the bonding wires and the differential signal leads, the insertion loss can be reduced when high frequency signal is transmitted from the bonding wires to the differential signal lead.

4. With the foregoing advantages, the lead arrangement and the chip package using the lead arrangement of the present invention can improve the signal transmission quality of differential signal leads.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A lead arrangement, applied in a leadframe for a chip package, the lead arrangement comprising:
at least a pair of differential signal leads including a first differential signal lead and a second differential signal lead; and
at least a non-differential signal lead disposed between the first differential signal lead and the second differential signal lead.

2. The lead arrangement of claim 1, wherein the first differential signal lead transmits a positive signal and the second differential signal lead transmits a negative signal, and the transmission direction of the first differential signal lead and the transmission direction of the second differential signal lead are identical.

3. The lead arrangement of claim 1, wherein the non-differential signal lead is a floating lead.

4. The lead arrangement of claim 1, wherein the non-differential signal lead is a power lead.

5. The lead arrangement of claim 1, wherein the non-differential signal lead is a ground lead.

6. A chip package, suitable for mounting on a circuit board, the chip package comprising:
a chip having an active surface and a plurality of bonding pads disposed thereon;
a leadframe having a die pad and a plurality of leads, wherein the chip is disposed on the die pad and some of the leads form a lead arrangement, the lead arrangement includes:
at least a pair of differential signal leads including a first differential signal lead and a second differential signal lead; and
at least a non-differential signal lead disposed between the first differential signal lead and the second differential signal lead;
a plurality of bonding wires, wherein each bonding pad on the chip is electrically connected to one of the leads in the leadframe through a corresponding bonding wire; and
a molding compound encapsulating the chip, the bonding wires, the die pad and a portion of the leads.

7. The chip package of claim 6, wherein the first differential signal lead transmits a positive signal and the second differential signal lead transmits a negative signal, and the transmission direction of the first differential signal lead and the transmission direction of the second differential signal lead are identical.

8. The chip package of claim 7, wherein the transmission direction of the first differential signal lead and the transmission direction of the second differential signal lead are from the chip to the circuit board.

9. The chip package of claim 7, wherein the transmission direction of the first differential signal lead and the transmission direction of the second differential signal lead are from the circuit board to the chip.

10. The chip package of claim 6, wherein the non-differential signal lead is a floating lead.

11. The chip package of claim 10, wherein the non-differential signal lead and any of the bonding pads are not electrically connected.

12. The chip package of claim 6, wherein the non-differential signal lead is a power lead.

13. The chip package of claim 6, wherein the non-differential signal lead is a ground lead.

14. The chip package of claim 6, wherein some of the bonding wires cross each other.

15. The chip package of claim 6, wherein some of the bonding pads are arranged to correspond to the lead arrangement of the leads in the leadframe.

16. A chip package comprising:
a leadframe having a die pad, a plurality of differential signal leads, and a plurality of non-differential signal leads;
a chip having a plurality of bonding pads, wherein the chip is disposed on the die pad;
a plurality of bonding wires for connecting the leads and the bonding pads; and
a molding compound encapsulating the chip, the bonding wires, the die pad and a portion of the leads;
wherein each of the differential signal leads connects its corresponding bonding pad through its corresponding bonding wire;
wherein at least one differential signal lead is disposed between one pair of non-differential signal leads;
wherein two of the differential signal leads are disposed at the two sides of the rest leads.

17. The chip package of claim 16, wherein each of the non-differential signal leads connects its corresponding bonding pad through its corresponding bonding wire.

18. The chip package of claim 17, wherein the bonding wire of one non-differential signal lead crosses the bonding wire of its corresponding differential signal lead.

19. The chip package of claim 16, wherein the chip package is used for mounting on a circuit board.

20. The chip package of claim 16, wherein the number of the bonding pads is smaller than the number of the leads.
